(19) United States
(12) Patent Application Publication
(10) Pub. No.: US 2011/0039414 A1
(43) Pub. Date: Feb. 17, 2011

(54) PLASMA PROCESSING METHOD AND PLASMA PROCESSING APPARATUS

(75) Inventor: Youichirou Aya, Osaka (JP)

Correspondence Address: DITTHAVONG MORI & STEINER, P.C., 918 Prince Street, Alexandria, VA, 22314, US

(73) Assignee: SANYO ELECTRIC CO.,LTD., Moriguchi-shi (JP)

(21) Appl. No.: 12/922,961

(22) PCT Filed: Mar. 18, 2009
(86) PCT No.: PCT/JP2009/055311

§ 371 Date: Oct. 28, 2010

(30) Foreign Application Priority Data
Mar. 19, 2008 (JP) 2008-072495

(51) Int. Cl. H01L 21/3065; H01L 21/302

(52) U.S. Cl. 438/710; 156/345.1; 438/758; 257/E21.218; 257/E21.214

(57) ABSTRACT

An upper electrode 20 according to one embodiment of the present invention includes: a counter portion 22 having a counter face 22A facing a placing face 10A; a periphery portion 24 having a flat face 24A connecting to a periphery of the counter face 22A; and multiple convex portions 26 formed on the counter face 22A. On a projection plane substantially parallel to the placing face 10A, the periphery of the counter portion 22 overlaps the periphery of the lower electrode 10, and a periphery of the periphery portion 24 surrounds a periphery of the counter portion 22.

### TECHNICAL FIELD

The present invention relates to a plasma processing method and a plasma processing apparatus which perform plasma processing on a substrate.

### BACKGROUND ART

Generally, plasma processing apparatuses which perform plasma processing such as plasma CVD processing and plasma etching processing on a substrate are broadly used in manufacturing steps of semiconductor devices. A plasma processing apparatus includes: a lower electrode including a placing face on which a substrate is placed; and an upper electrode including a counter face facing the placing face. Planer shapes of the lower and upper electrodes are substantially the same. Application of a voltage between the lower and upper electrodes generates plasma in a processing space provided between the lower and upper electrodes.

Conventionally, there has been a proposal of a method in which multiple convex portions are formed all over the counter face of the upper electrode (refer to Japanese Patent Application Laid-open Publication No. 2002-241946). According to this method, high-density plasma can be generated in the processing space by causing electrons located around that convex portion to be accelerated in accordance with an electric field gradient formed inside each of the convex portions.

Here, in order to uniformly perform plasma processing on a substrate, it is desirable that uniform plasma be generated on the placing face. For example, in a case where plasma CVD processing is performed on a substrate, deposition is performed on the substrate with uniform film thicknesses and uniform film quality by having plasma uniformly generated on the placing face.

However, in a case where the multiple convex portions are formed all over the counter face of the upper electrode, an electric filed intensity tends to be weaker on an edge portion of the placing face than on a central portion of the placing face. As a result, plasma cannot be uniformly generated on the placing face, and it has been difficult to uniformly perform plasma processing on a substrate.

The present invention was made in consideration of the above described situation, and an object thereof is to provide a plasma processing method and a plasma processing apparatus capable of uniformly generating plasma on the placing face.

### SUMMARY OF THE INVENTION

A plasma processing method according to the aspect of the present invention is summarized as a plasma processing method, comprising the step of: performing plasma processing on a substrate, using a plasma processing apparatus, wherein the plasma processing apparatus includes a first electrode having a placing face on which the substrate is placed, and a second electrode including: a counter portion having a counter face facing the placing face; a periphery portion having a flat face connecting to a periphery of the counter face; and multiple convex portions formed on the counter face wherein: on a projection plane substantially parallel to the placing face, a periphery of the counter portion overlaps a periphery of the first electrode, and a periphery of the periphery portion is arranged so as to surround the periphery of the counter portion.

In the plasma processing method according to the aspect of the present invention, the multiple convex portions may be formed on a substantially entire region of the counter face.

In the plasma processing method according to the aspect of the present invention, the periphery face may be a plane substantially parallel to the placing face.

In the plasma processing apparatus according to the aspect of the present invention, a plasma processing apparatus according to the aspect of the present invention is summarized as a plasma processing apparatus which performs plasma processing on a substrate, comprise: a first electrode having a placing face on which the substrate is placed; and a second electrode including: a counter portion having a counter face facing the placing face; a periphery portion having a flat face connecting to a periphery of the counter face; and a plurality of convex portions formed on the counter face, wherein: on a projection plane substantially parallel to the placing face, a periphery of the counter portion overlaps a periphery of the first electrode, and a periphery of the periphery portion surrounds the periphery of the counter portion.

According to the present invention, a plasma processing method and a plasma processing apparatus capable of uniformly generating plasma can be provided.

### BRIEF DESCRIPTION OF THE DRAWINGS

FIG. 1 is a schematic view of a plasma processing apparatus 100 according to an embodiment of the present invention.

FIG. 2 is a projection view of a lower electrode 10 and an upper electrode 20 according to the embodiment of the present invention.

FIG. 3 is a schematic view of a processing space I according to the embodiment of the present invention.

FIG. 4 is a schematic view showing an electrode configuration of Example.

FIG. 5 is a schematic view showing an electrode configuration of Comparative Example.

FIG. 6 is a diagram showing electric field intensities in a region X of Example, and in a region Y of Comparative Example.

FIG. 7 is a diagram showing a relationship between film thicknesses and electric field intensities.

### DESCRIPTION OF THE PREFERRED EMBODIMENTS

Next, an embodiment of the present invention will be described by use of the drawings. In the following description of the drawings, the same or corresponding elements are denoted with the same or corresponding reference numerals. However, the drawings are schematic, and it should be noted that proportions between dimensions and the like are not actual. Consequently, specific dimensions and the like should be determined in consideration of the following description. Additionally, it is obvious that the drawings include parts which differ in relations and proportions between the drawings.

### (Configuration of Plasma Processing Apparatus)

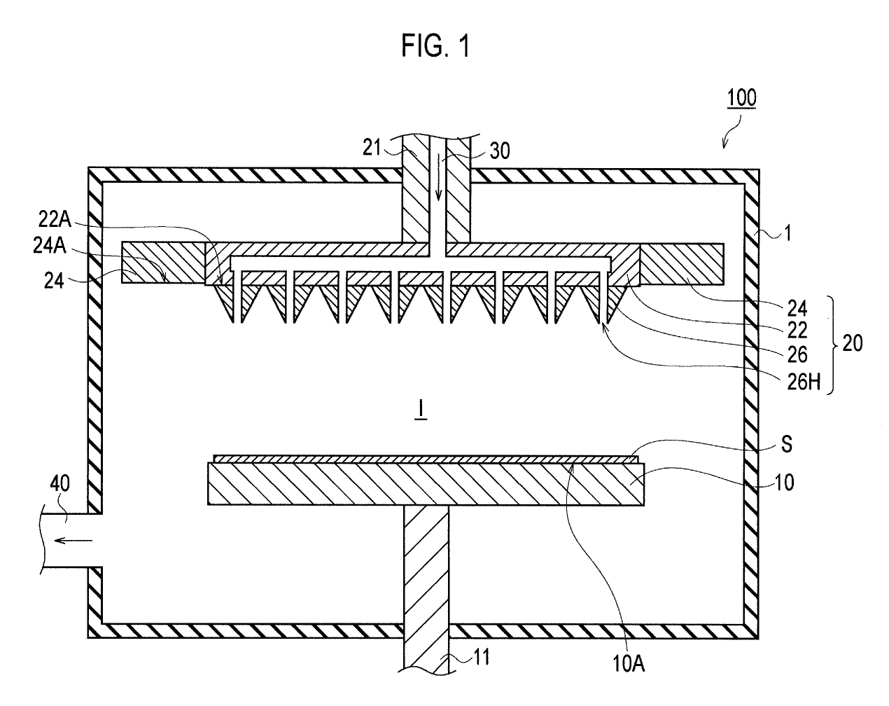

With reference to FIG. 1, a configuration of a plasma processing apparatus 100 according to the embodiment of the present invention will be described. FIG. 1 is a schematic view of the plasma processing apparatus 100.

In this embodiment, the plasma processing apparatus 100, which performs deposition processing on a substrate S by using a plasma enhanced chemical vapor deposition (PECVD) method, will be described as one example of plasma processing apparatuses.

The plasma processing apparatus 100 includes a vacuum chamber 1, a lower electrode 10, an upper electrode 20, a gas supply passage 30 and a gas discharge passage 40.

The vacuum chamber 1 is a processing container obtained by molding, for example, aluminum into a cylinder.

The lower electrode 10 functions as a placing table including a placing face 10A on which the substrate S is placed. The lower electrode 10 is supported by a support portion 11 so as to be vertically movable.

Additionally, the lower electrode 10 is connected to ground through the support portion 11, thereby functioning as an anode electrode. In an inside of the lower electrode 10, a heating mechanism (unillustrated) formed of, for example, molybdenum wire is provided. When plasma processing is performed on the substrate S, the lower electrode 10 is heated by the heating mechanism. The lower electrode 10 is formed of general electrically-conductive material such as carbon, graphite or aluminum.

The upper electrode 20 includes a counter portion 22, a periphery portion 24 and multiple convex portions 26. The upper electrode 20 is supported by a support portion 21 so as to be suspended from a ceiling of the vacuum chamber 1. A processing space I in which plasma is generated is formed between the lower electrode 10 and the upper electrode 20.

The counter portion 22 is arranged so as to face the lower electrode 10, and has a counter face 22A facing the placing face 10A of the lower electrode 10. The multiple convex portions described later are formed on a substantially entire region of the counter face 22A. Inside the counter portion 22, the gas supply passage 30 through which a deposition gas and a plasma-forming gas are supplied is provided.

The periphery portion 24 is provided so as to surround lateral sides of the counter portion 22. The periphery portion 24 has a flat face 24A connecting to a periphery of the counter face 22A of the counter portion 22. The flat face 24 A is flatly formed, and is substantially parallel to the placing face 10A included in the lower electrode 10.

Note that the periphery portion 24 may be provided as one unit with the counter portion 22, or as a unit separate from the counter portion 22. In a case where the periphery portion 24 is provided as a unit separate from the counter portion 22, the periphery portion 24 is fixed to the counter portion 22 by means of an electrically-conductive attachment (for example, a bolt).

The multiple convex portions 26 are formed on the counter face 22A. Each of the convex portions 26 is formed into a shape tapering toward the lower electrode 10 side. In the convex portion 26, a gas supply opening 26H is formed from a peak of the convex portion 26 toward an inside of the counter portion 22. Each of the gas supply openings 26H are connected to the gas supply passage 30, and deposition gas and plasma-forming gas are supplied to the processing space I from the peaks of the convex portions 26. Note that the multiple convex portions 26 may be provided as one unit with the counter portion 22, or as units separate from the counter portion 22.

Direct-current voltage or high-frequency voltage is applied to the thus configured upper electrode 20, as bias voltage, by use of an unillustrated power supply device. That is, the upper electrode 20 functions as a cathode electrode having higher potential than the lower electrode 10. Thereby, plasma is generated in the processing space I. In particular, high-density plasma is generated in the processing space I because electrons located around the convex portions 26 are accelerated in accordance with electric field gradients formed inside the respective convex portions 26.

The upper electrode 20 is formed of a general electrically-conductive material such as carbon, graphite or aluminum. Additionally, an aluminum-based insulating film such as alumina or a silicon-based insulating film may be formed on each of the surfaces of the counter face 22A, the plate face 24A and the convex portions 26.

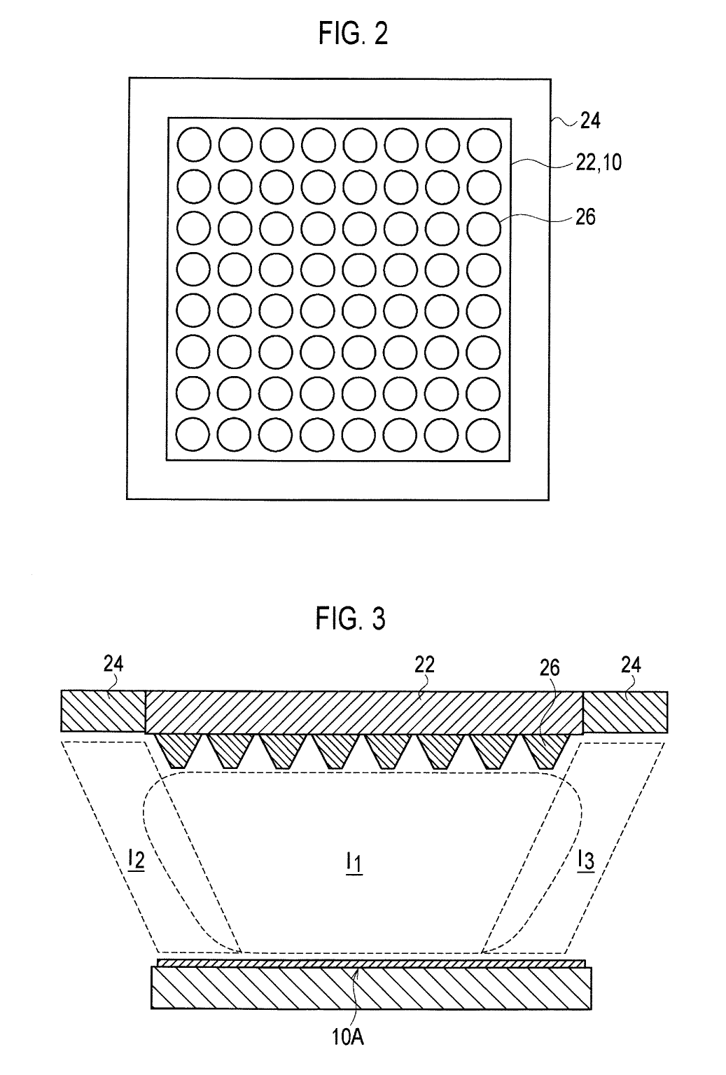

Here, FIG. 2 is a projection view in which the lower electrode 10 and the upper electrode 20 (the counter portion 22, the periphery portion 24 and the multiple convex portions 26) are projected on a projection plane substantially parallel to the placing face 10A of the lower electrode 10.

As shown in FIG. 2, the lower electrode 10 and the counter portion 22 have substantially equal dimensions, and a periphery of the counter portion 22 overlaps the periphery of the lower electrode 10. Additionally, a periphery of the periphery portion 24 surrounds the peripheries of the counter portion 22 and the lower electrode 10. Note that planar shapes of the lower electrode 10 and the upper electrode 20 are not limited to rectangles, and may be round shapes or the like.

The gas supply passage 30 is a gas supply tube for supplying a deposition gas and a plasma-forming gas to an inside of the vacuum chamber 1. Although only one gas supply passage 30 is shown in FIG. 1, a gas supply passage supplying a deposition gas and a gas supply passage supplying a plasma-forming gas may be provided separately.

A gas discharge passage 40 is a gas discharge tube for discharging gas inside the vacuum chamber 1, so that interior of the vacuum chamber 1 becomes a vacuum.

### (Electric Fields Formed in Processing Space)

Next, electric fields formed in the processing space I will be described with reference to FIG. 3. FIG. 3 is a schematic view of the lower electrode 10, the upper electrode 20 (the counter portion 22, the periphery portion 24 and the multiple convex portions 26) and the processing space I.

By the multiple convex portions 26 and the lower electrode 10, an electric field having a high electric field intensity is formed in a processing space I₁ shown in FIG. 3. Intensities of the electric field formed by the multiple convex portions 26 and the lower electrode 10 are weaker on an edge portion of the placing face 10A than on the central portion of the placing face 10A.

Additionally, by the periphery portion 24 and the lower electrode 10, electric fields are formed in processing spaces I₂ and I₃ shown in FIG. 3. That is, an electric field is formed on the edge portion of the placing face 10A by the periphery portion 24 and the lower electrode 10.

Thus, while an electric field is formed on the central portion of the placing face 10A by the multiple convex portions 26 and the lower electrode 10, an electric field is formed on the edge portion of the placing face 10A by the periphery portion 24 and the lower electrode 10.

### (Functions and Effects)

The upper electrode 20 according to this embodiment includes: the counter portion 22 having the counter face 22A facing the placing face 10A of the lower electrode 10; the periphery portion 24 having the flat face 24A connecting to the periphery of the counter face 22A; and the multiple convex portions 26 formed on the counter face 22A. On a projection plane substantially parallel to the placing face 10A, while the periphery of the counter portion 22 overlaps the periphery of the lower electrode 10, the periphery of the periphery portion 24 surrounds the periphery of the counter portion 22.

Accordingly, while an electric field is formed on the central portion (in the processing space I₁ in FIG. 3) of the placing face 10A by the multiple convex portions 26 and the lower electrode 10, electric fields are formed on the edge portion (in processing spaces I₂ and I₃ shown in FIG. 3) of the placing face 10A by the periphery portion 24 and the lower electrode 10. Thereby, plasma can be uniformly generated on an entire region of the placing face 10A, and plasma processing can be uniformly performed on the substrate S. In particular, by the plasma processing apparatus 100 according to this embodiment, deposition can be performed on the substrate S with uniform film thicknesses and uniform film quality.

In a conventional plasma processing apparatus not being provided with the periphery portion 24, plasma cannot be sufficiently generated on an edge portion of a placing face. Accordingly, dimensions of the substrate S have to be reduced to a substantial degree. Meanwhile, by the plasma processing apparatus 100 according to this embodiment, deposition can be performed on the substrate S with uniform film thicknesses and uniform film quality, even in a case where the substrate S is made in the same dimensions as those of the placing face 10A.

### Other Embodiments

While the present invention has been described through the abovementioned embodiment, discussions and drawings, which constitute parts of this disclosure, should not be understood as limiting this invention. Through this disclosure, various alternative embodiments, examples and operational technologies will be apparent to those skilled in the art.

For example, in the above embodiment, while description has been given to the case where deposition processing is performed on the substrate S by using the plasma processing apparatus 100, other plasma processing such as plasma etching processing may be performed by the plasma processing apparatus 100.

Additionally, while a potential of the lower electrode 10 is set to the ground potential in the above-mentioned embodiment by having the lower electrode 10 connected to the ground, it is only necessary that the potential of the lower electrode 10 be negative to that of the upper electrode 20.

Additionally, while the lower electrode 10 and the upper electrode 20 have been described as examples of a first electrode and a second electrode of the present invention, respectively, in the abovementioned embodiment, arrangement of the first electrode and the second electrode is not limited to the above arrangement. That is, the first electrode and the second electrode may be set standing substantially vertically to a horizontal face, or the first electrode may be arranged over the second electrode.

Additionally, while the flat face 24A is set substantially parallel to the placing face 10A in the abovementioned embodiment, the flat face 24A may be inclined in respect to the placing face 10A.

### EXAMPLES

An example of the plasma processing apparatus according to the present invention will be described below. Specifically, electric field intensities on the placing table were calculated, and effects of those intensities on deposition were considered.

### Example

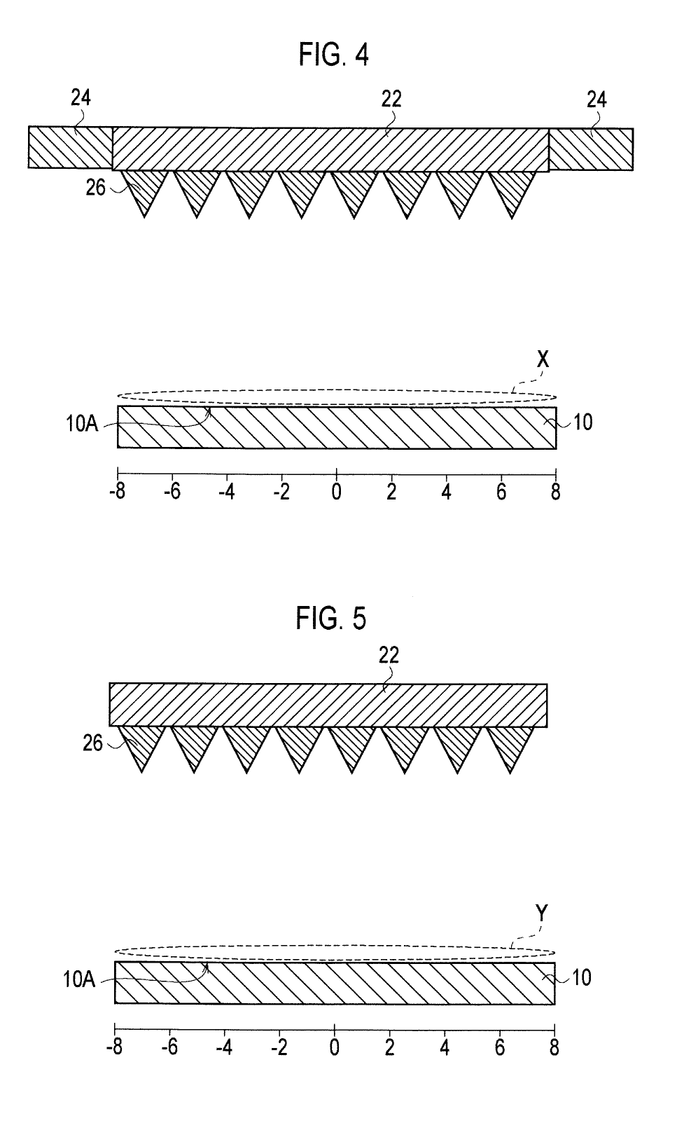

Based on an electrode configuration shown in FIG. 4, electric field intensities above the placing face 10A (in a region X) of the lower electrode 10 were calculated.

The upper electrode 20 according to Example includes the counter portion 22 facing the placing face 10A, a periphery portion 24 surrounding lateral sides of the counter portion 22 and the multiple convex portions 26 formed on the counter portion 22.

### Comparative Example

Based on an electrode configuration shown in FIG. 5, electric field intensities above the placing face 10A (in a region Y) of the lower electrode 10 were calculated.

The upper electrode 20 according to Comparative Example was the same as the one in Example described above expect that Comparative Example does not include the periphery portion 24.

### (Calculation Results)

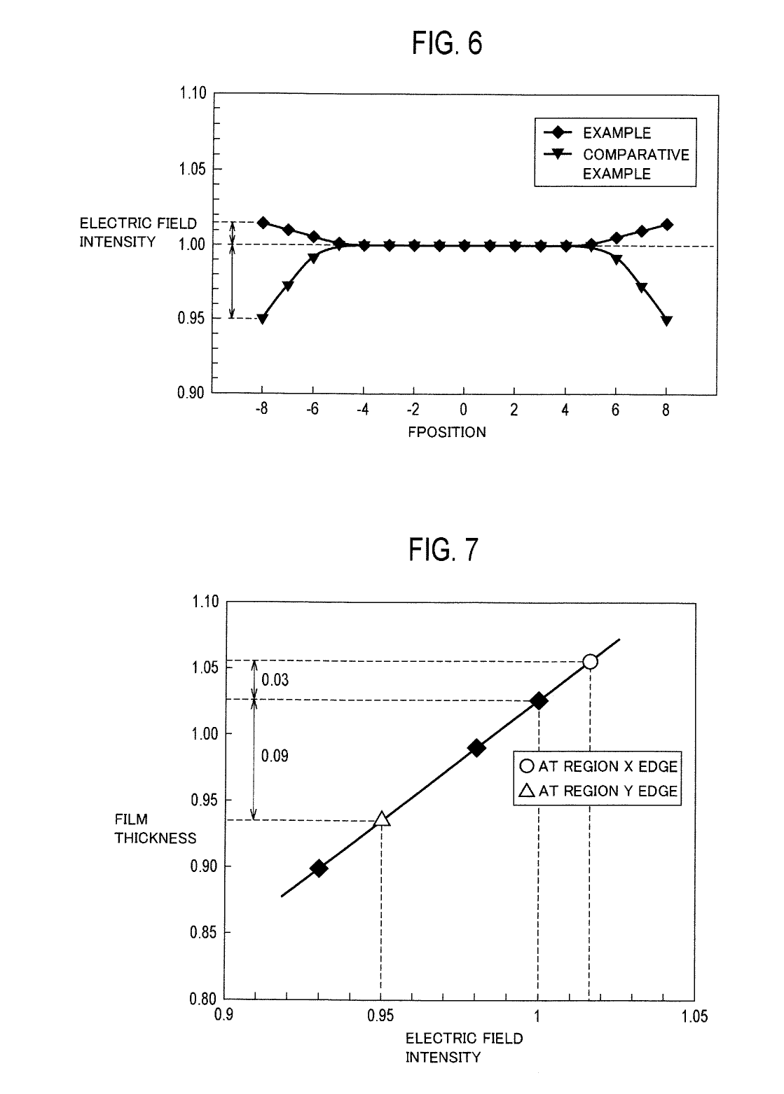

Electric field intensities in the region X and in the region Y are shown in FIG. 6. In FIG. 6, there are shown: positions relative to the center of the placing face 10A; and electric field intensities standardized on the basis of electric field intensities at the center of the placing face 10A.

As shown in FIG. 6, in Example, a ratio of the electric field intensity at an edge of the region X to the electric field intensity at the center of the region X was about 1.01. Meanwhile, in Comparative Example, a ratio of the electric field intensity at an edge of the region Y to the electric field intensity at the center of the region Y was about 0.95.

Thus, in Example, an electric field was more uniformly formed above the placing face 10A than in Comparative Example. This is because the electric field intensity on the edge portion of the placing face 10A was intensified by providing the periphery portion 24 in the upper electrode 20.

(Relationship between Film Thicknesses and Electric Field Intensities)

Next, a relationship between film thicknesses and electric field intensities was confirmed. Specifically, deposition processing was performed on a glass substrate by using the PECVD method. As processing conditions, a pressure was set to 1100 Pa, a temperature in an inside of a vacuum chamber to 200° C., a frequency of a voltage applied to an upper electrode to 40 MHz, an input power to 1.1 kw, and a ratio of a H₂ supply to an SiO₂ supply to 19.

FIG. 7 shows a relationship between film thicknesses of films formed on the glass substrate and values calculated as electric field intensities above the glass substrates. In FIG. 7, the electric field intensities and the film thicknesses are shown in the form of standardized values.

As shown in FIG. 7, it was confirmed that a film thickness is proportional to an electric field intensity. Based on FIG. 7, it was found that, if deposition processing is performed on a substrate by use of the plasma processing apparatus according to Example, variation in film thickness between the center of the region X and the edge of the region X is suppressed approximately within 3%.

Meanwhile, based on FIG. 7, it was found that, if deposition processing is performed on a substrate by use of the plasma processing apparatus according to Comparative Example, about 9% variation in film thickness is expected to occur between the center of the region Y and the edge of the region Y.

It was therefore confirmed that deposition processing resulting in more uniform film thicknesses can be performed by providing the periphery portion 24.

### INDUSTRIAL APPLICABILITY

As described above, the present invention can provide a plasma processing method and a plasma processing apparatus capable of uniformly generating plasma on the placing face, and is accordingly useful in the field of manufacturing of semiconductor.

What is claimed is:

1. A plasma processing method, comprising the step of:
performing plasma processing on a substrate, using a plasma processing apparatus, wherein
the plasma processing apparatus includes a first electrode having a placing face on which the substrate is placed; and
a second electrode including: a counter portion having a counter face facing the placing face; a periphery portion having a flat face connecting to a periphery of the counter face; and a plurality of convex portions formed on the counter face, wherein:
on a projection plane substantially parallel to the placing face,
a periphery of the counter portion overlaps a periphery of the first electrode, and
a periphery of the periphery portion is arranged so as to surround the periphery of the counter portion.

2. The plasma processing method according to claim 1, wherein the plurality of convex portions are formed on a substantially entire region of the counter face.

3. The plasma processing method according to any one of claims 1 and 2, wherein the periphery face is a plane substantially parallel to the placing face.

4. A plasma processing apparatus which performs plasma processing on a substrate, comprising:
a first electrode having a placing face on which the substrate is placed; and
a second electrode including: a counter portion having a counter face facing the placing face; a periphery portion having a flat face connecting to a periphery of the counter face; and a plurality of convex portions formed on the counter face, wherein:
on a projection plane substantially parallel to the placing face,
a periphery of the counter portion overlaps a periphery of the first electrode, and
a periphery of the periphery portion surrounds the periphery of the counter portion.
